(19) United States
(12) Patent Application Publication
(10) Pub. No.: US 2001/0005610 A1
(43) Pub. Date: Jun. 28, 2001

(54) Semiconductor device having metal silicide film and manufacturing method thereof

(76) Inventors: Tadashi Fukase, Tokyo (JP); Makoto Matsuo, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 09/742,474

(22) Filed: Dec. 22, 2000

Related U.S. Application Data
(62) Division of application No. 09/265,555, filed on Mar. 9, 1999.

(30) Foreign Application Priority Data
Mar. 11, 1998 (JP) 59688/1998

(51) Int. Cl. H01L 21/8242; H01L 21/44

(52) U.S. Cl. 438/239; 438/253; 438/683

(57) ABSTRACT

The present invention discloses a semiconductor device, and a manufacturing method thereof, which is obtained by forming a logic circuit part capable of performing a high speed arithmetic processing and memory cell part of a DRAM having a high information holding characteristic, on the same substrate.

In a semiconductor device in which a first MOS transistor having high concentration impurity diffused layers as source and drain regions are formed in a logic circuit part, and a second MOS transistor having relatively low concentration impurity diffused layers as source and drain regions are formed in a memory cell part of the DRAM, the device is given a structure where metal silicide films are formed on the impurity diffused layers of the first transistor, whereas no metal silicide films are formed on the impurity diffused layers of the second transistor.

### BACKGROUND OF THE INVENTION

1. Field of the Invention

The present invention relates to a semiconductor device, and more particularly to a structure and a manufacturing method of a semiconductor device having a metal silicide film on impurity diffused layers of the semiconductor device which has logic circuits and memory cells of a DRAM on the same substrate.

2. Description of the Related Art

In recent years, devices are being manufactured in which the logic device and the DRAM are formed on the same substrate.

As a related art, a schematic sectional view of a device having a logic device and a DRAM formed on the same substrate is illustrated in FIG. 3.

In a logic circuit part A of FIG. 3, there are formed a MOS transistor having a high concentration n-type impurity diffused layers 8 as the source and drain regions, and a MOS transistor having a high concentration p-type impurity diffused layers 9 as the source and drain regions. In a memory cell part B of the DRAM, there are formed MOS transistors with short gate length having a relatively low concentration impurity diffused layer 4 as the source and drain regions, in order to achieve a high density integration and to minimize the leakage current in the source-drain junction. In the source and drain regions of the transistors in the memory cell part B, there are formed a bit contact 11 for establishing connection with a bit line 12, and capacitor contacts 13 for establishing connection with a lower electrode 14 of a storage capacitor. In each of the impurity diffused layers 4, 8, and 9, there is formed a film 10 of such metal silicide as titanium silicide for reducing the resistance.

In addition, wells are formed in a silicon substrate 1 as appropriate, but they are omitted from the drawing.

In FIG. 7 are shown sectional views illustrating the process flow for manufacturing the semiconductor device shown in FIG. 3.

As shown in FIG. 7A, after formation of an element isolation oxide film 2 on a silicon substrate 1, a gate insulating film is formed by subjecting the substrate 1 to thermal oxidation or the like, then a conductive film and an insulating film such as silicon oxide film are laminated, and gate electrodes 3 having an insulating film 5 on the top surface are formed by patterning.

Following that, an n-type impurity such as phosphorus and arsenic is selectively implanted to the regions which are to become the source-drains of the n-channel transistors in the memory cells and in the logic circuit part A at a relatively low dose of about 5×10¹² to 3×10¹³/cm² to form impurity diffused layers 4 and 24. Further, a p-type impurity such as boron is selectively introduced to the region which is to become the source-drain of a p-channel transistor in the logic circuit part A to form a low concentration p-type diffused layer 25.

Next, as shown in FIG. 7B, an insulating film 6-1 such as silicon oxide film which is to become the gate electrode sidewall film is deposited on the entire surface of the substrate 1. Following that, the insulating film 6-1 is etched back by anisotropic etching to form spacers 6-2 and 6-3 of insulating film on the sidewalls of the gate electrodes 3.

Further, as shown in FIG. 7C, impurities such as phosphorus or arsenic and boron or boron fluoride are implanted selectively to the n-channel transistor and the p-channel transistor, respectively, in the logic circuit part A, at respective doses of 8×10¹⁴ to 5×10¹⁵/cm² to form an n-type impurity diffused layer 8 and a p-type impurity layer 9 of high concentration.

Next, a film of metal such as titanium is deposited on the entire surface by sputtering or the like, and by subjecting the film to a heat treatment, metal silicide films 10-1, 10-2, and 10-3 are formed on the impurity diffused layers 8, 9, and 4, respectively. In this case, metal silicide films 10 are formed in self-alignment by removing the residual excess metal film not reacting with silicon and the metal film on the insulating films using a solution which does not etch the metal silicide.

Following that, as shown in FIG. 7D, a bit line 12, a storage capacitor lower electrode 14, a storage capacitor upper electrode 15, metal wirings 16, and the like are formed, completing the semiconductor device.

In a semiconductor device thus formed, a metal silicide film is formed on the impurity diffused layers of the transistors, so the resistance of the impurity diffused layers is reduced, and a high speed operation of the logic circuit becomes possible.

However, it has been found that the semiconductor device obtained as in the above has the following problems.

Namely, in the memory cell transistor, the impurity concentration of the source-drain is normally set at a relatively low level because the source-drain dielectric breakdown voltage is lowered and the leakage current between the source and the drain in the sub-threshold region of the transistor is increased, if the level of the impurity concentration is set high. Now, in this kind of junction, the depletion layer extends towards the substrate surface as a voltage is applied to the drain. Accordingly, in the above device, when a voltage is applied to the drain, the depletion layer extends towards the metal silicide layer 10-3 due to the fact that a metal silicide film 10-3 is formed also on the low concentration n-type impurity diffused layer 4 which constitutes the source and drain regions of the MOS transistor of the memory cell, resulting in the increase in current leakage at the junction via the crystal defects introduced at the time of formation of the metal silicide film.

Although such a problem can be resolved by raising the impurity concentration of the source-drain region of the memory cell transistor, a raise of the impurity concentration leads to an increase in the current leakage between the source and the drain as mentioned above.

Furthermore, when the concentration of the impurity diffused layer 4 is low, a Schottky barrier is formed between the metal silicide film 10-3 and the impurity diffused layer 4, which also results in the problem of increase in the contact resistance of the bit contact 11 and the capacitor contact 13.

### SUMMARY OF THE INVENTION

It is therefore the object of the present invention to provide a more satisfactory semiconductor device and a manufacturing method of the same, which can resolve the above-mentioned problems in the related art.

In order to resolve the above problems, the semiconductor device according to this invention is characterized in that it is provided with a first MOS transistor formed in a first element formation region of a silicon substrate, and a second MOS transistor formed in a second element formation region of the silicon substrate, said first MOS transistor having a higher impurity concentration of a source region and a drain region compared with said second MOS transistor, wherein first and second metal silicide films are formed on said source and drain regions of said first MOS transistor, respectively, and no metal silicide films are formed on a source region and a drain region of said second MOS transistor.

The second MOS transistor has a shorter gate length compared with the first MOS transistor.

The first MOS transistor is for operating at high speed and the second MOS transistor constitutes a memory cell.

The impurity concentration of the source and drain regions of the first MOS transistor is higher than the impurity concentration of the source and drain regions of the second MOS transistor.

The metal silicide films are silicide films of either one metal of titanium, cobalt, molybdenum, or tungsten.

The first MOS transistor is a transistor for constituting a logic circuit part, and the second MOS transistor is a transistor for constituting a memory cell part.

The semiconductor device further comprises first and a second connection pads on the source and drain diffused layer of the second MOS transistor, respectively.

Each of the first and second connection pads is further provided with a metal silicide film on its top surface.

The conductive films which forms the first and second connection pads are polycrystalline silicon or single crystal silicon.

The semiconductor device according to this invention further includes a bit line formed above the second MOS transistor, and a capacitor comprising of a lower electrode, a capacitor insulating film, and an upper electrode formed above the bit line, wherein the first connection pad and the bit line are connected electrically via a bit contact hole, and the second connection pad and the lower electrode are connected electrically via capacitor contact hole.

The semiconductor device according to this invention further includes an insulating film which is formed on the gate electrode of the second MOS transistor and on the first and second connection pads, and exposes at least a part of the top surface of each of the first and second connection pads, wherein the bit contact is formed on the mentioned part in the top surface of the first connection pad, and the capacitor contact is formed on the mentioned part in the top surface of the second connection pad.

Further, the manufacturing method of the semiconductor device according to this invention is characterized in that the method includes a step of forming a first MOS transistor in a first element formation region of the silicon substrate and forming second MOS transistor in a second element formation region of the silicon substrate, a step of forming either first and second connection pads formed of conductive films which directly contact with the source and drain diffused layers of the second MOS transistor, respectively, and a step of forming metal silicide films on the source and drain regions of the first MOS transistor after the formation of the first and second connection pads.

In the step of forming the metal silicide film, the metal silicide films are formed also on the first and second connection pads.

The step of forming the metal silicide film on the source and drain regions of the first MOS transistor is carried out in the state wherein the surface of the gate electrodes of the second MOS transistor and the surface of the first and second connection pads are covered with an insulating film.

According to this invention with the above constitution, it is possible to resolve such problems as the increase in the current leakage at the junction and the increase in the contact resistance in the bit contact and the capacitor contact.

### BRIEF DESCRIPTION OF THE DRAWINGS

The above and other objects, advantages, and features of the present invention will be more apparent from the following description taken in conjunction with the accompanying drawings, in which:

FIG. 1 is a schematic sectional view showing an example of a semiconductor device according to the present invention;

FIG. 2 is a schematic sectional view showing another example of the semiconductor device according to the invention;

FIG. 3 is a schematic sectional view of the semiconductor device for describing a related art;

FIGS. 4A-4D show schematic sectional views for describing the first half of an example of a manufacturing method of the semiconductor device according to the invention;

FIGS. 5A-5C show schematic sectional views for describing the latter half of the manufacturing method (FIG. 4) of the semiconductor device according to the invention;

FIGS. 6A-6D show schematic sectional views for describing another example of the manufacturing method according to the invention; and

FIGS. 7A-7D show schematic sectional views for describing an example of the manufacturing method of the semiconductor device of the related art shown in FIG. 3.

### DESCRIPTION OF THE PREFERRED EMBODIMENTS

Referring to the drawings, the embodiments of the present invention will be described in the following.

### Embodiment 1

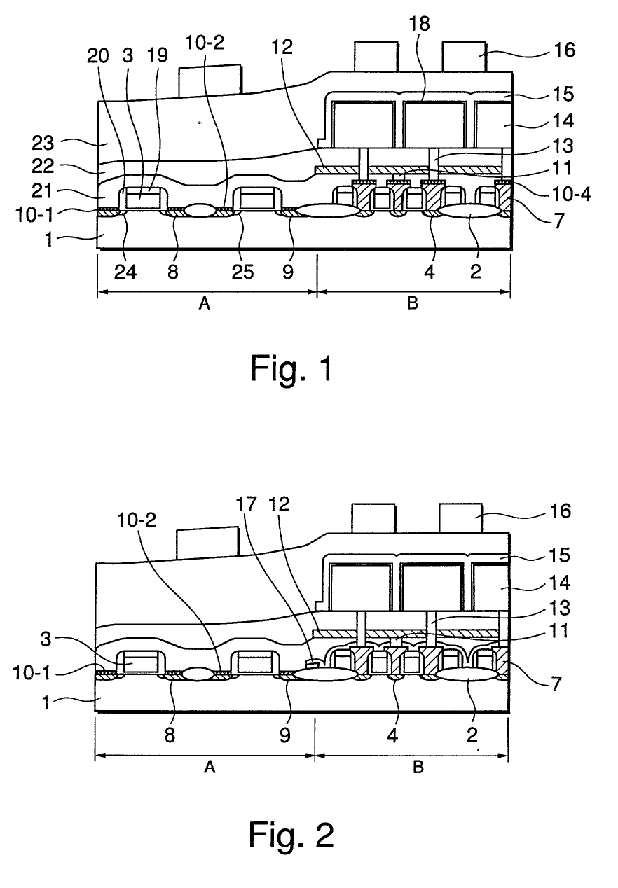

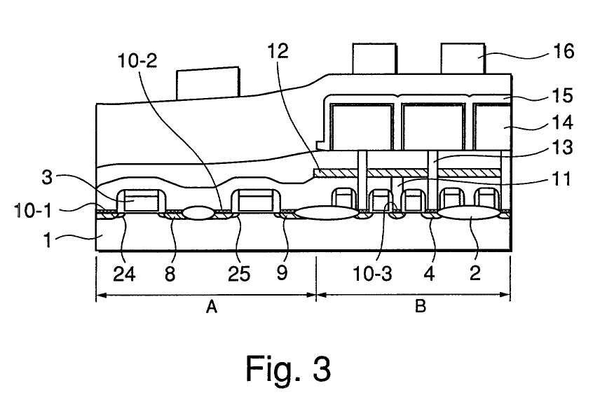

As shown in FIG. 1, in a logic circuit part A of a silicon substrate 1, an n-channel MOS transistor of LDD structure having a low concentration n-type impurity diffused layers 24 and uses a high concentration n-type impurity diffused layers 8 as the source and drain regions, and a p-channel MOS transistor of LDD structure having a low concentration p-type impurity layers 25 and uses a high concentration p-type impurity diffused layers 9 as the source and drain regions. In a memory cell part B, there are formed memory cell transistors having a low concentration n-type impurity diffused layers 4. On the n-type diffused layers 4, there are formed connection pads 7 so as to fill in the spaces between the gate electrodes 3 of the memory cell transistors. The connection pads 7 is formed of polycrystalline silicon which contains phosphorus to about 1×10²⁰/cm³. On the impurity diffused layers 8 and 9 in the logic circuit part A and on the connection pads 7 of the memory cell part B, there are formed metal silicide films 10-1, 10-2, and 10-4, respectively. In the memory cell part B, a bit line 12 is formed on an interlayer insulating film 21, and a capacitor consisting of a lower electrode 14, an upper electrode 15, and a capacitor insulating film 18 is formed on an interlayer insulating film 22. Further, the bit line 12 and the capacitor lower electrode 14 are connected to the source and drain regions of the memory cell transistors by a bit contact 11 and capacitor contacts 13, respectively. Furthermore, an interlayer insulating film 23 is formed so as to cover the capacitor, and metal wirings 16 are formed on the interlayer insulating film 23.

Furthermore, the connection pads 7 are provided for securing electrical connection of the bit line 12 and the impurity diffused layer 4, and the lower electrode 14 of the capacitor and the impurity diffused layer 4, respectively.

As in the above, in this embodiment, a metal silicide film 10-4 is formed on the connection pads 7 which are above the impurity diffused layers 4 of the memory cell transistors. In other words, there does not exist metal silicide films which directly contact with the n-type impurity diffused layers 4. Because of this, there is an effect that the problems of the increase in the current leakage and the increase in the contact resistance of the bit contact 11 and the capacitor contact 13 do not arise even if the impurity concentration of the n-type impurity diffused layers 4 is low.

Next, the method of manufacturing the semiconductor device shown in FIG. 1 will be described.

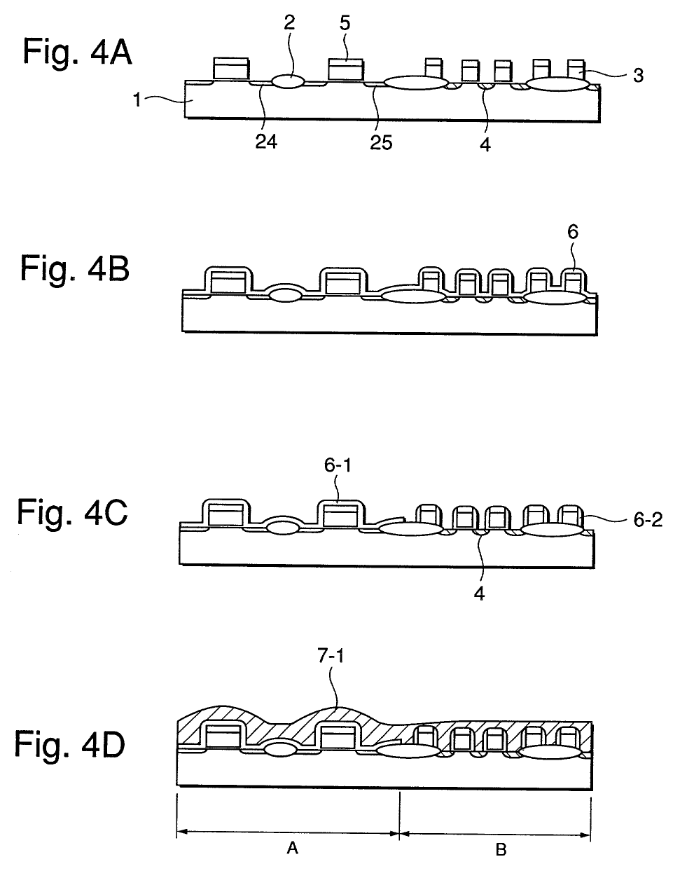

As shown in FIG. 4A, after forming an element isolation oxide film 2 on the silicon substrate 1, a gate insulating film is formed by subjecting the substrate 1 to a thermal oxidation. Further, a conductive film such as polycrystalline silicon film and an insulating film such as silicon oxide film are laminated, and gate electrodes 3 having an insulating film 5 on the top surface are formed by patterning the laminated films.

Then, the impurity diffused layer 4 which is to become the source-drains of the memory cell transistors is formed in the memory cell part B by selectively implanting ions of an n-type impurity such as phosphorus at a dose of about (1 to 3)×10¹³/cm². Simultaneously with this, the n-type impurity is implanted also in the region which is to become the source-drain of the n-channel transistor in the logic circuit part A to form a low concentration impurity diffused layers 24 in order to give an LDD structure to the transistor in the logic circuit part A. In addition, a low concentration p-type impurity diffused layers 25 is also formed by selectively implanting ions of a p-type impurity such as boron in the region which is to become the source-drain of the p-channel transistor in the logic circuit part A.

Next, as shown in FIG. 4B, an insulating film 6 such as silicon oxide film which is to become the gate electrode sidewall films is deposited on the entire surface of the substrate 1.

Following that, as shown in FIG. 4C, anisotropic etching is carried out in the state where the logic circuit part A is masked, in order to expose the impurity diffused layer 4 by allowing only the insulating film 6 in the memory cell part B to be etched back. By so doing, sidewall spacer films 6-2 is formed on the sidewalls of the gate electrodes of the memory cell transistors in the memory cell part B while an insulating film 6-1 remains on the logic circuit part A.

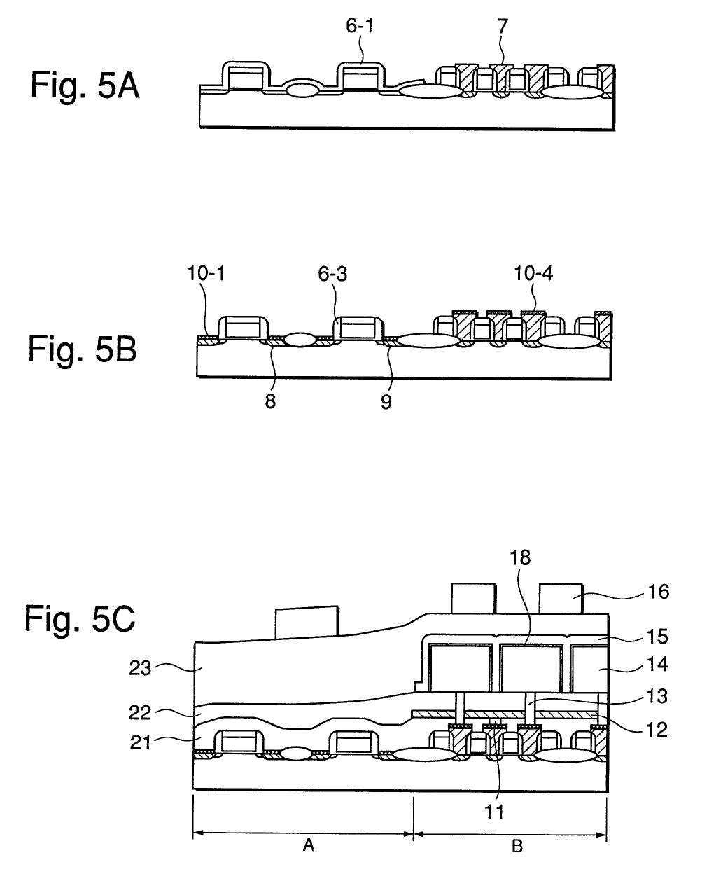

Next, as in FIG. 4D, a polycrystalline silicon film 7-1 is deposited. After that, connection pads 7 are formed by patterning the polycrystalline silicon film 7-1 as shown in FIG. 5A.

Next, as shown in FIG. 5B, sidewall spacer films 6-3 are formed on the sidewalls of the gate electrodes in the logic circuit part A by etching back the insulating film 6-1 in the logic circuit part A, followed by the formation of n-type impurity diffused layers 8 and p-type impurity diffused layers 9. The n-type diffused layers 8 are formed by implanting ions of, for example, arsenic at about 8×10¹⁴ to 5×10¹⁵/cm², and the p-type impurity diffused layers 9 are formed by implanting ions of, for example, boron fluoride at about 8×10¹⁴ to 5×10¹⁵/cm².

Further, a film of metal such as titanium, tungsten, molybdenum, or cobalt is deposited by sputtering, and metal silicide films 10-1 and 10-4 are formed on the impurity diffused layers 8 and 9 in the logic circuit part A and on the connection pads 7 in the memory cell part B by subjecting the metal film to a heat treatment. In this case, it is possible to form metal silicide films 10 in self-alignment by removing the excess metal film remained unreacting with silicon and the metal film on the insulating film using a solution which does not etch the metal silicide film. Here, a heat treatment for recovering crystal defects caused by the ion implantation may be introduced after the formation of the impurity diffused layers 8 and 9 and before the deposition of the metal film.

After that, an interlayer insulating film 21 made of a BPSG, a bit contact 11 made of impurity doped polycrystalline silicon, a bit line 12 made of an impurity doped polycrystalline silicon, an interlayer insulating film 22, capacitor contacts 13 made of impurity doped polycrystalline silicon, a storage capacitor lower electrode 14 made of impurity doped polycrystalline silicon, a capacitor insulating film 18 made of a silicon nitride film, a storage capacitor upper electrode 15 made of impurity doped polycrystalline silicon, an interlayer insulating film 23, and aluminum metal wirings 16 are formed sequentially, completing the logic circuit part A and the memory cell part B as shown in FIG. 5C.

In this embodiment, the effect mentioned in the above is realized since metal silicide films are not formed on the source-drain impurity diffused layers of the memory cell transistors. Therefore, a semiconductor device which takes the above-mentioned effect can be provided.

However, when the integration level is raised and the spacing between the memory cell transistors is reduced in embodiment 1, there arises a possibility of having a short-circuit between connection pads because the bridge of the metal silicide film 10-4 is formed on the adjacent connection pads 7.

Accordingly, a semiconductor device which dissolves such a problem will be described as embodiment 2 in the following.

### Embodiment 2

As shown in FIG. 2, an n-channel MOS transistor and a p-channel MOS transistor are formed in a logic circuit part A in a silicon substrate 1 similar to embodiment 1 in FIG. 1. In a memory cell part B, memory cell transistors are formed, and connection pads 7 are formed on n-type impurity diffused layers 4 of the memory cell transistors so as to fill in the spaces between the gate electrodes 3. In addition, metal silicide films 10-1 and 10-2 are formed on the impurity diffused layers 8 and 9, respectively, of the logic circuit part A. In embodiment 2, differing from embodiment 1, a metal silicide film is not formed on the connection pads 7. Instead of it, an insulating film 17 such as silicon oxide film is formed so as to cover the connection pads and the gate electrodes, and the bit contact 11 and the capacitor contacts 13 are in direct contact with the connection pads 7.

A manufacturing method of the semiconductor device in FIG. 2 will be described in the following.

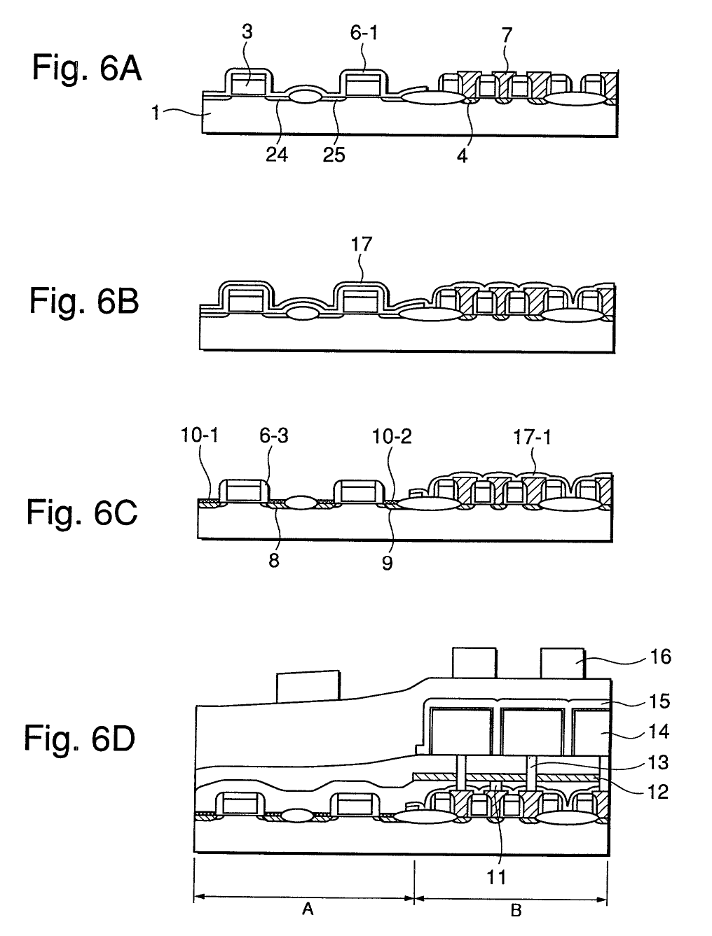

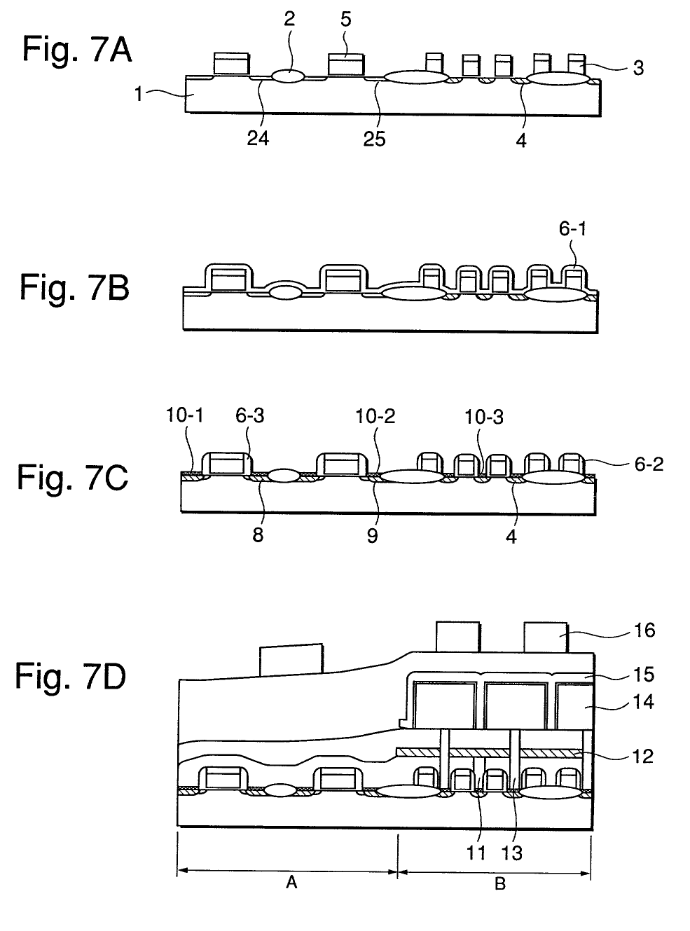

As shown in FIG. 6A, in the same way as in the processes up to FIG. 5A of embodiment 1, gate electrodes 3, impurity diffused layers 4, 24, and 25 are formed on the silicon substrate 1, and connection pads 7 are formed in the memory cell part B. The insulating film 6-1 is left intact in logic circuit part A.

Next, as shown in FIG. 6B, an insulating film 17 such as silicon oxide film of about 30 to 100 nm thickness is deposited on the entire surface.

Following that, as shown in FIG. 6C, an insulating sidewall films 6-3 is formed on the sidewalls of the gate electrodes in the logic circuit part A by etching back the insulating film 17 and the insulating film 6-1 in the state in which the memory cell part B is masked. Further, an n-type impurity diffused layers 8 are formed by selectively implanting ions of, for example, arsenic at a dose of about 8×10¹⁴ to 5×10¹⁵/cm², and p-type impurity diffused layers 9 are formed by selectively implanting ions of, for example, boron fluoride at a dose of about 8×10¹⁴ to 5×10¹⁵/cm².

After that, metal silicide films 10-1 and 10-2 are formed on the impurity diffused layers 8 and 9 by depositing a film of metal such as titanium by sputtering, and then subjecting the metal film to a heat treatment. In this case, it is possible to form the metal silicide films 10 in self-alignment by removing the excess metal film remaining unreacted with silicon and the metal film on the insulating film by using a solution which does not etch the metal silicide films. In this case, metal silicide films are not formed on the connection pads 7 in the memory cell part B since the pads are covered with the insulating film 17-1.

A heat treatment for recovering the crystal defects caused by the ion implantation may be introduced after the formation of the impurity diffused layers 8 and 9, and before the deposition of the metal film.

Following that, as shown in FIG. 6D, the bit contact 11, bit line 12, capacitor contacts 13, storage capacitor lower electrode 14, storage capacitor upper electrode 15, metal wirings 16 and the like are formed, completing the logic circuit part A and the memory cell part B of the DRAM.

According to this embodiment, similar to embodiment 1, it is possible to prevent the problems of increase in the current leakage and increase in the contact resistance of the bit contact 11 and the capacitor contacts 13. Moreover, the defect of having electrical short-circuit between adjacent connection pads that are spaced closely caused by the bridging of the metal silicide films can be dissolved since no metal silicide film is formed on the connection pads 7 in the memory cell part B.

In the present embodiment, an example is shown in which the bit contact 11, bit line 12, capacitor contacts 13, capacitor lower electrode 14, and capacitor upper electrode 15 are formed of polycrystalline silicon film, but a refractory metal such as tungsten may be used for these conductive films. In such a case, it is preferable to use a high dielectric constant film such as tantalum oxide as the capacitor insulating film 18 instead of a nitride film. With such a constitution, it is possible to reduce the temperature of the subsequent heat treatment by carrying out a heat treatment for activating the impurities in the polycrystalline silicon film of connection pads 7 and the impurities in the impurity diffused layers 8, 9, and 4 right after the connection pads 7 are formed.

As described in detail in the above, according to this invention, metal silicide films of titanium silicide or the like are formed on the n-type impurity diffused layers and the p-type impurity diffused layers of the transistors in the logic circuit part A, so that the resistances of the impurity diffused layers are lowered and a high speed operation of the device becomes possible. Moreover, since no metal silicide film is formed on relatively low concentration n-type impurity diffused layers of the memory cell transistors in the memory cell part B, current leakage at the junction can be suppressed to a low level and the information holding property can be enhanced.

The above-mentioned structure can be obtained by carrying out the step of forming the metal silicide film after the formation of the connection pads in the memory cell part B, and forming the metal silicide film on the connection pads and the metal silicide film on the impurity diffused layers in the logic circuit part A at the same time.

Furthermore, by adopting a structure in which no metal silicide film is formed on the connection pads in the memory cell part B as in embodiment 2, it is possible to prevent the defect of having electrical short-circuit caused by the bridging of the metal silicide films when the connection pads are formed adjacent with each other with a small spacing.

It is apparent that the present invention is not limited to the above embodiments, but may be modified and changed without departing from the scope and spirit of the invention.

What is claimed is:

1. A semiconductor device having a first MOS transistor formed in a first element formation region of a silicon substrate, and a second MOS transistor formed in a second element formation region of said silicon substrate, said first MOS transistor having a higher impurity concentration of a source region and a drain region compared with said second MOS transistor, wherein first and second metal silicide films are formed on said source and drain regions of said first MOS transistor, respectively, and no metal silicide films are formed on a source region and a drain region of said second MOS transistor.

2. The semiconductor device as claimed in claim 1, wherein said second MOS transistor has a shorter gate length compared with said first MOS transistor.

3. The semiconductor device as claimed in claim 1, wherein said first MOS transistor is for operating at high speed and said second MOS transistor constitutes a memory cell.

4. The semiconductor device as claimed in claim 1, wherein said first and second metal silicide films are silicide films of either one selected from among the group consisting of titanium, cobalt, molybdenum, and tungsten.

5. The semiconductor device as claimed in claim 1, wherein said first MOS transistor is a transistor for constituting a logic circuit and said second MOS transistor is a transistor for constituting a memory cell.

6. The semiconductor device as claimed in claim 1, further comprising first and second connection pads provided on said source and drain regions of said second MOS transistor, respectively.

7. The semiconductor device as claimed in claim 6, wherein third and fourth metal silicide films being provided on said first and second connection pads, respectively.

8. The semiconductor device as claimed in claim 6, wherein said first and second connection pads are made of polycrystalline silicon or single crystal silicon.

9. The semiconductor device as claimed in claim 6, further comprising a bit line formed above said second MOS transistor and a capacitor comprising a lower electrode, a capacitor insulating film and an upper electrode formed above said bit line, wherein said first connection pad and said bit line are electrically connected via a bit contact hole and said second connection pad and said lower electrode of said capacitor are electrically connected via a capacitor contact hole.

10. The semiconductor device as claimed in claim 9, further comprising an insulating film formed on the gate electrode of said second MOS transistor and on said first and second connection pads, wherein at least a part of each top surface of said first and second connection pads being exposed and said bit contact being formed on said exposed part of the top surface of said first connection pad and said capacitor contact being formed on said exposed part of the top surface of said second connection pad.

11. A manufacturing method of a semiconductor device comprising, forming a first MOS transistor in a first element formation region provided in a silicon substrate and a second MOS transistor in a second element formation region provided in said silicon substrate, forming a first and second connection pads which directly contact with a source region and a drain region of said second MOS transistor, respectively, and forming first and second metal silicide films on a source region and a drain region of said first MOS transistor, respectively, after the formation of said first and second connection pads.

12. The manufacturing method of a semiconductor device as claimed in claim 11, wherein third and fourth metal silicide films are formed on said first and second connection pads, respectively, in said forming said first and second metal silicide films.

13. The manufacturing method of a semiconductor device as claimed in claim 11, wherein an impurity concentration of said source and drain regions of said first MOS transistor is higher than an impurity concentration of said source and drain regions of said second MOS transistor.

14. The manufacturing method of a semiconductor device as claimed in claim 11, wherein said first and second metal silicide films are silicide films of either one selected from among the group consisting of titanium, cobalt, molybdenum, and tungsten.

15. The manufacturing method of a semiconductor device as claimed in claim 11, wherein said first MOS transistor is a transistor for constituting a logic circuit and said second MOS transistor is a memory cell transistor for constituting a memory cell.

16. The manufacturing method of a semiconductor device as claimed in claim 11, wherein said first and second connection pads are made of polycrystalline silicon or single crystal silicon.

17. The manufacturing method of a semiconductor device as claimed in claim 10, wherein said forming first and second metal silicide films is carried out in the state in which a top surface of the gate electrode of said second MOS transistor and top surfaces of said first and second connection pads are covered with an insulating film.

18. The manufacturing method of a semiconductor device as claimed in claim 15 further comprising forming a first interlayer insulating film on said second MOS transistor, forming a bit contact which is electrically connected to said first connection pad on said first connection pad, selectively forming a bit line which is electrically connected to said bit contact over said second element formation region on said first interlayer insulating film, forming a second interlayer insulating film on said bit line, forming a capacitor contact which is electrically connected to said second connection pad on said second connection pad, forming a capacitor lower electrode which is electrically connected to said capacitor contact on said second interlayer insulating film over said second element formation region, and forming a capacitor insulating film and a capacitor upper electrode on said capacitor lower electrode.
